(19) United States
(12) Patent Application Publication
(10) Pub. No.: US 2025/0366066 A1
(43) Pub. Date: Nov. 27, 2025

(54) THIN-FILM TRANSISTOR AND PREPARATION METHOD THEREFOR, AND MEMORY AND DISPLAY

(71) Applicant: INSTITUTE OF MICROELECTRONICS OF THE CHINESE ACADEMY OF SCIENCES, Beijing (CN)

(72) Inventors: Xinlv DUAN, Beijing (CN); Ling LI, Beijing (CN); Ming LIU, Beijing (CN); Di GENG, Beijing (CN); Congyan LU, Beijing (CN)

(73) Assignee: INSTITUTE OF MICROELECTRONICS OF THE CHINESE ACADEMY OF SCIENCES, Beijing (CN)

(21) Appl. No.: 18/873,659

(22) PCT Filed: Aug. 31, 2022
(86) PCT No.: PCT/CN2022/116070

§ 371 Date: Dec. 10, 2024

(30) Foreign Application Priority Data
Jun. 10, 2022 (CN) 202210657327.0

(51) Int. Cl. H10D 30/67; H10D 30/01; H10D 62/10; H10D 62/13

(52) U.S. Cl. CPC H10D 30/6757; H10D 30/0312; H10D 30/0318; H10D 30/6728; H10D 30/673; H10D 30/6737; H10D 62/102; H10D 62/151

(57) ABSTRACT

Disclosed herein are a thin-film transistor and a preparation method therefor, and a memory and a display. The thin-film transistor comprises a first source/drain layer (1); a second source/drain layer (3); an insulating layer (2), which is located between the first source/drain layer (1) and the second source/drain layer (3); a channel layer (4), which is embedded in the first source/drain layer (1) and the insulating layer (2); and a gate electrode (5), which is embedded in the channel layer (4), wherein an embedded end of the channel layer (4) is in contact with the second source/drain layer (3), and a top end of the channel layer (4) and a top end of the gate electrode (5) are both flush with the first source/drain layer (1). The thin-film transistor provided in the present disclosure is a CAA architecture in which an annular channel is arranged surrounding the gate electrode (5), such that the performance of the transistor can be improved, and the power consumption can be reduced; moreover, there is no gate electrode (5) in the horizontal direction covering the first source/drain layer (1), such that the parasitic capacitance and current leakage of the gate electrode can be reduced.

### CROSS-REFERENCE TO RELATED PATENT APPLICATIONS

This application claims a priority from the Chinese Patent Application No. 202210657327.0, filed with the Chinese Patent Office on Jun. 10, 2022, entitled “THIN-FILM TRANSISTOR AND PREPARATION METHOD THEREFOR, AND MEMORY AND DISPLAY”, content of which is incorporated herein by reference in its entirety.

### FIELD OF THE INVENTION

The disclosure relates to a thin film transistor, a preparation method therefor, a memory, and a display.

### BACKGROUND OF THE INVENTION

According to Moore's Law, integrated circuits continue to develop towards finer dimensions, and advanced fabrication process is one of the most cutting-edge nodes of integrated circuit fabrication. Currently, advanced fabrication process has evolved to nodes of 5/7 nm, which places extremely high demands on further miniaturization of transistor.

The design of a Fin Field Effect Transistor (FinFET), which is one key architecture for the current transistor, can greatly improve circuit control and reduce leakage current, while greatly shortening the gate length of the transistor. However, the architecture of the FinFET is suitable for 10-22 nm process. For processes below 10 nm, such as 7 nm, 5 nm, and 3 nm, it will be limited by the scaling of FinFET width and cannot guarantee high performance and low power consumption while continuing to shrink in size. On the other hand, further improvement of the process results in a larger leakage current at the gate of the FinFET, and a reduced performance with more power consumption.

Therefore, it becomes an urgent problem to be solved how to further reduce the size of the transistor, improve performance of the transistor, reduce power consumption and reduce leakage current of the gate.

### SUMMARY OF THE INVENTION

According to the present disclosure, there is provided a thin film transistor and a method for preparing the same, a memory and a display, solving the technical problem of how to further reduce the size of the transistor, improve performance of the transistor, reduce power consumption and reduce leakage current of the gate.

In a first aspect, according to the present disclosure, there is provided a thin film transistor including:
a first source/drain layer; a second source/drain layer; an insulating layer located between the first source/drain layer and the second source/drain layer; a channel layer embedded within the first source/drain layer and the insulating layer; and a gate embedded within the channel layer, in which an embedded end of the channel layer is in contact with the second source/drain layer, and a top end of the channel layer and a top end of the gate are both flush with the first source/drain layer.

In a second aspect, according to the present disclosure, there is provided a method for preparing a thin film transistor including:
providing a substrate; forming in sequence a second source/drain layer, an insulating layer and a first source/drain layer on the substrate; forming a hole extending to the second source/drain layer within the first source/drain layer and the insulating layer; depositing a channel material on an inner wall of the hole and a surface of the first source/drain layer; depositing a gate material on the channel material; removing the channel material and the gate material on the surface of the first source/drain layer to form a gate and a channel layer with top ends being flush with the first source/drain layer.

In a third aspect, according to the present disclosure, there is provided a memory including a plurality of storage arrays which include the thin film transistor according to the first aspect.

In a fourth aspect, according to the present disclosure, there is provided a display including a pixel circuit which includes the thin film transistor according to the first aspect.

According to the present disclosure, there is provided a thin film transistor, in which a gate of the thin film transistor passes through a first source/drain layer and an insulating layer, and an annular channel surrounds the gate to form an architecture of Channel All Around, which is referred to as a transistor with CAA architecture. Compared with a transistor with FinFET architecture, the transistor with CAA architecture according to the present disclosure has the following advantages. Firstly, compared with a planar channel structure, a vertical channel structure reduces the horizontal area occupied of an electrode by stacking source/drain electrodes, which can significantly reduce the size of the transistor and facilitate reducing the device unit density. The channel length is determined by the thickness of the insulating layer, and the miniaturization of the channel length is not limited by the lithography process, which is conducive to achieve a smaller channel length, thereby increasing the channel width to length ratio, enabling greater device current and reducing power consumption. Secondly, the CAA architecture with the annular channel surrounding the gate can greatly increase the contact area between the gate and the channel, thereby significantly enhancing the control ability of the gate on the channel, and improving current conduction efficiency. Compared with a GAA (Gate All Around) architecture, the CAA architecture also has a larger contact area between the gate and channel. Thirdly, there is no gate coverage above the first source/drain layer in the horizontal direction, which can avoid overlap between the gate and the first source/drain layer in the horizontal direction, and reduce parasitic capacitance and leakage current of the gate.

The foregoing description is merely a summary of the technical solutions of the present disclosure. In order that the technical means of the present disclosure can be more clearly understood to be practiced in light of the description, and in order that the above and other objects, features and advantages of the present disclosure can be more clearly understood, the specific embodiments of the present disclosure are set forth as follows.

### BRIEF DESCRIPTION OF THE DRAWINGS

FIG. 1 is a structural schematic diagram of a thin film transistor according to an embodiment of the present disclosure;

FIG. 2 is a schematic flowchart of a method for preparing a thin film transistor according to an embodiment of the present disclosure; and

FIG. 3 is a schematic diagram of a storage array according to an embodiment of the present disclosure.

Reference signs are denoted as follows:

1. first source/drain layer; 2. insulating layer; 3. second source/drain layer; 4. channel layer; 5. gate; 6. gate dielectric layer; 71. first thin film transistor; 72. second thin film transistor.

### DETAILED DESCRIPTION OF THE INVENTION

In order to enable those skilled in the art to understand the present disclosure more clearly, the technical solutions of the present disclosure will be described in detail through specific embodiments with reference to the accompanying drawings. Throughout the specification, unless otherwise specifically stated, the terms used herein are to be understood as having the meanings commonly used in the art. Thus, unless otherwise defined, all technical and scientific terms used herein have the same meaning as commonly understood by one of ordinary skill in the art to which this disclosure belongs. If there is a contradiction, the present specification preferably takes precedence. Unless otherwise specified, various devices and the like used in the present disclosure may be obtained through market purchase or may be prepared by existing methods.

In the description of the present disclosure, it should be noted that the orientation or position relationship indicated by the terms “center”, “upper”, “lower”, “left”, “right”, “vertical”, “horizontal”, “inner”, “outer” and the like is based on the orientation or position relationship shown in the accompanying drawings, or the orientation or position relationship normally placed when the product is used is merely for ease of description, rather than indicating or implying that the device or element referred to has to have a specific orientation, and is constructed and operated in a specific orientation, and therefore cannot be understood as a limitation to the present disclosure. In addition, the terms “first”, “second”, “third”, and the like are only used to distinguish descriptions, and cannot be understood as indicating or implying relative importance.

In addition, terms such as “horizontal”, “vertical”, and “overhang” do not indicate that a component is required to be absolutely horizontal or suspended, but may be slightly inclined. For example, “horizontal” means that the direction thereof is relatively horizontal relative to “vertical”, and does not indicate that the structure is necessarily completely horizontal, but may be slightly inclined.

Researches show that the reason why a large leakage current occurs in the gate of a transistor is as follows. In order to facilitate wiring, a gate of the transistor with vertical structure usually extends horizontally on an upper surface of an upper source/drain layer, and therefore the gate and the upper source/drain layer have an overlapping region in the horizontal direction. As the size of the transistor further shrinks, a significant leakage current will be generated between the gate and the upper source/drain layer in the overlapping region.

Based on above, in a first aspect, according to the present disclosure, there is provided a Thin Film Transistor (TFT), whose structure is shown in FIG. 1, including:
a first source/drain layer 1;
a second source/drain layer 3;
an insulating layer 2 located between the first source/drain layer 1 and the second source/drain layer 3;
a channel layer 4 embedded within the first source/drain layer 1 and the insulating layer 2; and
a gate 5 embedded within the channel layer 4,
in which an embedded end of the channel layer 4 is in contact with the second source/drain layer 3, and a top end of the channel layer 4 and a top end of the gate 5 are both flush with the first source/drain layer 1.

For ease of understanding, the first source/drain layer 1 provided in this embodiment can be regarded as an upper source/drain of the TFT, and the second source/drain layer 3 can be regarded as a lower source/drain of the TFT. In actual use, the second source/drain layer 3 may be prepared as a source and the first source/drain layer 1 as a drain, or the second source/drain layer 3 may also be prepared as a drain and the first source/drain layer 1 as a source, which is not specifically limited herein.

The insulating layer 2 is located between the first source/drain layer 1 and the second source/drain layer 3, and plays an insulating role.

The gate 5 is of a vertical gate structure, and the bottom of the gate 5 at least penetrates the first source/drain layer 1 and enters the second insulating layer 2. The bottom of the gate 5 can also penetrate the insulating layer 2 and enter the second source/drain layer 3.

The shape of the gate 5 may be cylindrical, and the cross-sectional shape of the gate 5 may be circular, elliptical or polygonal. The shape of the gate 5 may also be annular, and the cross-sectional shape of the gate 5 may be a circular ring, an elliptical ring, or a polygonal ring, which may be determined according to practical requirement. The optional materials for the gate 5 are Indium Tin Oxide (ITO), Indium Zinc Oxide (IZO), or Titanium Nitride (TiN).

The channel layer 4 is of a vertical channel structure, which is formed around the gate 5 within the first source/drain layer 1 and the insulating layer 2. Therefore, the TFT transistor according to the present embodiment belongs to a CAA (Channel All Around) architecture in which an annular channel fully surrounds the gate. The cross-sectional shape of the channel layer 4 may be circular, elliptical or polygonal, and the cross-sectional shape of the channel layer 4 may be the same as or different from the cross-sectional shape of the gate 5.

Materials for the channel layer 4 may be Indium Gallium Zinc Oxide (IGZO) or other metal oxide channel materials.

In some embodiments, the thin film transistor further includes a gate dielectric layer 6 located between the gate 5 and the channel layer 4. Optional material for the gate dielectric layer 6 includes at least one of hafnium oxide, hafnium aluminum oxide, and aluminum oxide.

Hereto, the vertical transistor of CAA architecture according to the present embodiment has the following characteristics.

1) Compared with a planar channel structure, a vertical channel structure reduces the horizontal area occupied by an electrode by stacking source/drain electrodes, which can significantly reduce the size of the transistor and facilitate reducing the device unit density. The channel length is determined by the thickness of the insulating layer 2, and the miniaturization of the channel length is not limited by the lithography process, which is conducive to achieve a smaller channel length, thereby increasing the channel width to length ratio, enabling greater device current and reducing power consumption.

2) The CAA architecture with the annular channel surrounding the gate can greatly increase the contact area between the gate 5 and the channel layer 4, thereby significantly enhancing the control ability of the gate 5 on the channel layer 4, and improving current conduction efficiency. Compared with the GAA (Gate All Around) architecture, the CAA architecture also has a larger contact area between the gate 5 and the channel layer 4.

In order to reduce the leakage current between the gate 5 and the upper source/drain layer, the top ends of both the channel layer 4 and the gate 5 are controlled to be flush with the first source/drain layer 1 when preparing the transistor. The flush may be that the planes of the top ends of the gate 5 and the channel layer 4 are aligned with the upper surface or the plane of the top end of the first source/drain layer 1, as shown in FIG. 1. It is also possible that the planes of the top ends of the gate 5 and the channel layer 4 are aligned with the plane of the bottom end of the first source/drain layer 1. It is also possible that the height difference between the planes of the top ends of the gate 5 and the channel layer 4 and the plane of the top end of the first source/drain layer 1 does not exceed a set value, which is determined according to requirements, such as not exceeding 5 nanometers.

By controlling the top ends of both the channel layer 4 and the gate 5 to be flush with the first source/drain layer 1, the thin film transistor provided in this embodiment further has the following characteristics.

3) When the top ends of both the channel layer 4 and the gate 5 are flush with the first source/drain layer 1, there is no gate coverage over the first source/drain layer 1 in the horizontal direction, which can avoid overlap between the gate 5 and the first source/drain layer 1 in the horizontal direction, and reduce parasitic capacitance and leakage current of the gate. Besides, the top end of the gate 5 being flush with the first source/drain layer 1 realizes the isolation of gates 5 between different devices, which can effectively reduce parasitic capacitance and power consumption of devices. At the same time, it also simplifies the graphical steps of multilayer materials in the preparation.

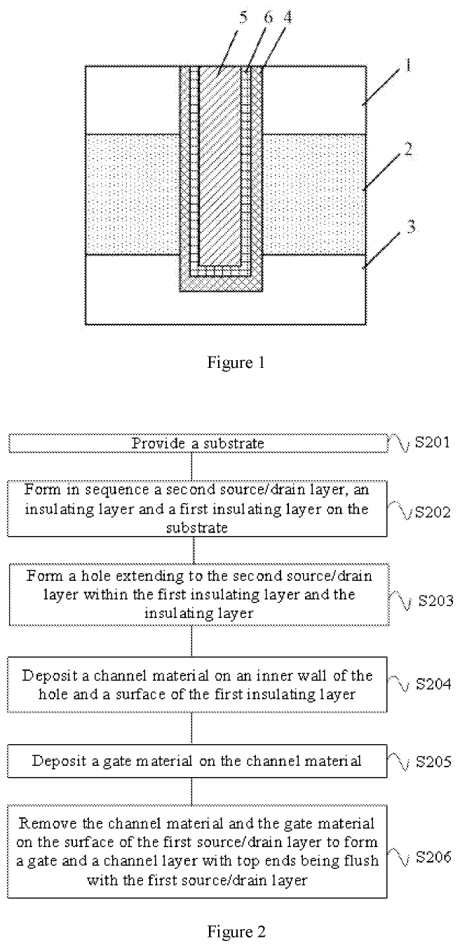

In a second aspect, as shown in FIG. 2, according to the present disclosure, there is provided a method for preparing a thin film transistor, including steps S201 to S206 as follows.

S201: Provide a substrate, where a silicon substrate may be used.

S202: Form in sequence a second source/drain layer 3, an insulating layer 2 and a first source/drain layer 1 on the substrate.

A pre-oxidation layer may be deposited on the substrate with a thickness of 300-400 nm, followed by pre-cleaning, and then a metal material layer forming the second source/drain layer 3 may be deposited on the pre-oxidation layer as follows. The pre-oxidation layer is pre-cleaned, and the source/drain metal material is deposited on the pre-cleaned pre-oxidation layer. A double protective layer is then deposited on the source/drain metal material layer, which may be a double protective layer formed of SiN and SiO, and the thickness of the double protective layer is about 200 nm. Next, the source/drain metal material layer is photolithographically processed. In particular, after the double protective layer is covered with the photoresist, exposure, development, and etching are performed in sequence to form a second source/drain layer 3.

Next, a fill oxide layer is deposited on the second source/drain layer 3, followed by chemical mechanical polishing and cleaning, and after completion, an insulating layer material is deposited to form the insulating layer 2.

Next, the steps for the second source/drain layer 3 are repeated on the insulating layer 2 to deposit the first source/drain metal material, and then deposition of a double protective layer, photoresist covering, exposure, development, etching, and cleaning are performed in sequence to form a first source/drain layer 1.

S203: Form a hole extending to the second source/drain layer 3 within the first insulating layer 1 and the insulating layer 2, where the required hole can be formed by deep etching as follows.

A fill oxide layer is deposited again on the first source/drain layer 1, followed by chemical mechanical polishing and cleaning. The polishing position stays on the fill oxide layer.

A through hole is formed as follows. A double protective layer (SiN+SiO) is deposited at the location where the through hole is to be formed, followed by covering of the photoresist, and then exposure, development, etching, cleaning and chemical mechanical polishing are performed, forming a through hole whose bottom reaches the first source/drain layer 1 and a through hole whose bottom reaches the second source/drain layer 3, respectively.

A channel hole is formed as follows. A double protective layer (SiN+SiO) is deposited at the location where the channel hole is to be formed, followed by covering of the photoresist. After aligning with the first source/drain layer 1, exposure, development, etching and cleaning are performed, forming a channel hole penetrating the first source/drain layer 1 and the insulating layer 2, whose bottom reaches the second source/drain layer 3.

S204: Deposit a channel material on an inner wall of the hole and a surface of the first source/drain layer 4.

S205: Deposit a gate material on the channel material.

S206: Remove the channel material and the gate material on the surface of the first source/drain layer 1 to form a gate 5 and a channel layer 4 with top ends being flush with the first source/drain layer 1.

In some embodiments, the channel material and the gate material are deposited in the channel hole. The deposition method may be atomic layer deposition. After depositing the gate material, the channel material and the gate material on the surface of the first source/drain layer 1 may be removed using grinding, polishing, or etching, so that the top ends of the gate 5 and the channel layer 4 are flush with the upper surface of the first source/drain layer 1.

In some embodiments, after depositing the channel material, a gate dielectric material is deposited first to form the gate dielectric layer 6, and then the gate material is deposited on a surface of the gate dielectric layer 7. The method for depositing the gate dielectric material may be atomic layer deposition.

In a third aspect, according to the present disclosure, there is provided a memory including a plurality of storage arrays which include the thin film transistor according to the first aspect.

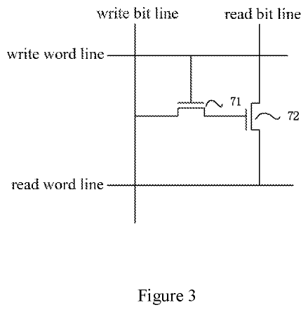

FIG. 3 shows an optional memory array structure of 2T0C in which one storage array includes two thin film transistors according to the embodiment of the present disclosure, i.e., a first thin film transistor 71 and a second thin film transistor 72. Herein, the gate of the first thin film transistor 71 is electrically connected to a write word line (WWL), the source is electrically connected to a write bit line (WBL), and the drain is electrically connected to the gate of the second thin film transistor 72. The source of the second thin film transistor 72 is electrically connected to a read word line (RWL), and the drain is electrically connected to a read bit line (RBL).

By applying the thin film transistor according to the embodiment of the present disclosure to the memory circuit of 2T0C, the gate of one TFT transistor can be directly connected to the source/drain of another TFT transistor, without the need for external lead, and thus the volume of the entire memory can be greatly reduced to facilitate further miniaturization of the memory.

In addition, the thin film transistor according to the embodiment of the present disclosure may also be applied to memory arrays of 1T0C, 1T1C, and 2T1C, which are not specifically limited herein.

In a fourth aspect, according to the present disclosure, there is provided a display including a pixel circuit which includes the thin film transistor according to the first aspect.

According to one or more embodiments of the present disclosure, the present disclosure has the following beneficial effects or advantages.

According to the present disclosure, there is provided a thin film transistor and a method for preparing the same, a memory and a display. In the thin film transistor, a gate of the thin film transistor passes through a first source/drain layer and an insulating layer, and an annular channel surrounds the gate to form an architecture of Channel All Around, which is referred to as a transistor with CAA architecture. Compared with a transistor with FinFET architecture, the transistor with CAA architecture according to the present disclosure has the following advantages. Firstly, compared with a planar channel structure, a vertical channel structure reduces the horizontal area occupied by an electrode by stacking source/drain electrodes, which can significantly reduce the size of the transistor and facilitate reducing the device unit density. The channel length is determined by the thickness of the first insulating layer, and the miniaturization of the channel length is not limited by the lithography process, which is conducive to achieve a smaller channel length, thereby increasing the channel width to length ratio, enabling greater device current and reducing power consumption. Secondly, the CAA architecture with the annular channel surrounding the gate can greatly increase the contact area between the gate and the channel, thereby significantly enhancing the control ability of the gate on the channel, and improving current conduction efficiency. Compared with a GAA (Gate All Around) architecture, the CAA architecture also has a larger contact area between the gate and channel. Thirdly, there is no gate coverage above the first source/drain layer in the horizontal direction, which can avoid gate overlap with the first source/drain layer in the horizontal direction, and reduce parasitic capacitance and leakage current of the gate.

Although the preferred embodiments of the present disclosure have been described, those of ordinary skill in the art can make additional changes and modifications to these embodiments once they learn the basic inventive concept. Therefore, the appended claims are intended to be interpreted as including the preferred embodiments and all changes and modifications falling within the scope of the present disclosure.

Obviously, those skilled in the art can make various modifications and variations to the present disclosure without departing from the spirit and scope of the present disclosure. In this way, if these modifications and variations of the present disclosure fall within the scope of the claims of the present disclosure and their equivalent technologies, the present disclosure is also intended to include these modifications and variations.

1. A thin film transistor comprising:
a first source/drain layer;
a second source/drain layer;
an insulating layer located between the first source/drain layer and the second source/drain layer;
a channel layer embedded within the first source/drain layer and the insulating layer; and
a gate embedded within the channel layer,
wherein an embedded end of the channel layer is in contact with the second source/drain layer, and a top end of the channel layer and a top end of the gate are both flush with the first source/drain layer.

2. The thin film transistor according to claim 1, wherein top ends of both the gate and the channel layer are flush with the first source/drain layer.

3. The thin film transistor according to claim 1, further comprising a gate dielectric layer which is located between the gate and the channel layer.

4. The thin film transistor according to claim 2, wherein the material for the gate dielectric layer includes at least one of hafnium oxide, hafnium aluminum oxide, and aluminum oxide.

5. The thin film transistor according to claim 1, wherein the cross-sectional shape of the channel layer is one of circular, elliptical or polygonal.

6. The thin film transistor according to claim 1, wherein the bottom of the gate is located within the second source/drain layer.

7. A method for preparing a thin film transistor comprising:
providing a substrate;
forming in sequence a second source/drain layer, an insulating layer and a first insulating layer on the substrate;
forming a hole extending to the second source/drain layer within the first insulating layer and the insulating layer;
depositing a channel material on an inner wall of the hole and a surface of the first insulating layer;
depositing a gate material on the channel material; and
removing the channel material and the gate material on the surface of the first source/drain layer to form a gate and a channel layer with top ends being flush with the first source/drain layer.

8. The method according to claim 7, wherein the removing of the channel material and the gate material on the surface of the first source/drain layer to form a gate and a channel layer with top ends being flush with the first source/drain layer comprises:
removing the channel material and the gate material on the surface of the first source/drain layer to form a gate and a channel layer with top ends being flush with an upper surface of the first source/drain layer.

9. A memory comprising a plurality of storage arrays which comprise the thin film transistor according to claim 1.

10. A display comprising a pixel circuit which comprises the thin film transistor according to claim 1.
